(19) United States
(12) Patent Application Publication
(10) Pub. No.: US 2025/0081828 A1
(43) Pub. Date: Mar. 6, 2025

(54) DISPLAY PANEL AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Yuan YAO, Hefei (CN); Bo RAO, Hefei (CN); Liusong NI, Hefei (CN); Lipeng GAO, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/663,188

(22) Filed: May 14, 2024

Related U.S. Application Data
(63) Continuation of application No. PCT/CN2024/087415, filed on Apr. 12, 2024.

(30) Foreign Application Priority Data
Aug. 31, 2023 (CN) 202311124847.6
Sep. 28, 2023 (CN) 202311287741.8

(51) Int. Cl. H10K 59/80; H10K 59/122; H10K 59/40

(52) U.S. Cl. CPC H10K 59/8792; H10K 59/122; H10K 59/40; H10K 59/873

(57) ABSTRACT

A display panel and a display apparatus. The display panel includes: a substrate, an isolation structure, a light-emitting functional layer, a touch layer, and a light-transmitting shielding layer. The isolation structure is arranged on a side of the substrate, and the isolation structure is configured to enclose a plurality of defining openings and a plurality of light-transmitting openings. The light-emitting functional layer includes a plurality of light-emitting portions. The light-emitting portion is at least partially arranged in the defining opening. The touch layer is arranged on a side of the isolation structure facing away from the substrate. The light-transmitting shielding layer is arranged between the isolation structure and the touch layer.

### CROSS-REFERENCE TO RELATED APPLICATIONS

This application is a continuation of International Application No. PCT/CN2024/087415, filed on Apr. 12, 2024, which claims priority to Chinese Patent Application No. 202311124847.6 filed on Aug. 31, 2023, and priority to Chinese Patent Application No. 202311287741.8 filed on Sep. 28, 2023, which are hereby incorporated by reference in their entireties.

### TECHNICAL FIELD

The present application relates to the technical field of display devices, and in particular to a display panel and a display apparatus.

### BACKGROUND

Liquid crystal display (LCD) panels, organic light emitting diode display (OLED) panels, and display panels using light emitting diode (LED) devices are widely used in various electronic products such as mobile phones, TVs, personal digital assistants, digital cameras, notebook computers, and desktop computers due to advantages such as high image quality, power saving, a thin body, and a wide range of applications.

Alight-emitting functional layer, a driving circuit layer, and a touch layer are arranged in a display panel. The driving circuit layer is configured to drive the light-emitting functional layer to emit light for display. The touch layer is configured to realize touch and control of the display panel by a user. The touch layer and the driving circuit layer are disposed on two opposite sides of the light-emitting functional layer respectively. Parasitic capacitance is generated between the touch layer and the driving circuit layer, causing radio frequency interference between them and reducing image quality of display on the display panel.

### SUMMARY

Embodiments of the present application provide a display panel and a display apparatus, which are intended to reduce or prevent generation of parasitic capacitance between the touch layer and the driving circuit layer and improve the image quality of display on the display panel.

An embodiment of a first aspect of the present application provides a display panel, including:
a substrate;
an isolation structure arranged on a side of the substrate, the isolation structure being configured to enclose a plurality of defining openings and a plurality of light-transmitting openings;
a light-emitting functional layer including a plurality of light-emitting portions, the light-emitting portion being at least partially arranged in the defining opening;
a touch layer arranged on a side of the isolation structure facing away from the substrate; and
a light-transmitting shielding layer arranged between the isolation structure and the touch layer, an orthographic projection of the light-transmitting shielding layer on the substrate being at least partially overlapped with an orthographic projection of the light-transmitting opening on the substrate.

An embodiment of a second aspect of the present application further provides a display apparatus, including the display panel in any one of the embodiments in the first aspect.

In the display panel and the display apparatus provided in the embodiments of the present application, the light-transmitting opening is provided, so as to increase light transmittance of the display panel; the light-transmitting shielding layer is arranged between the isolation structure and the touch layer, and the light-transmitting shielding layer is arranged to block at least part of the light-transmitting opening, so that radio frequency between the touch layer and the driving circuit layer that may pass through the light-transmitting opening can be blocked by the light-transmitting shielding layer, which prevents or reduces radio frequency interference between the touch layer and the driving circuit layer and improve image quality of display on the display panel.

### BRIEF DESCRIPTION OF THE DRAWINGS

In order to more clearly illustrate the technical solutions in embodiments of the present application, the accompanying drawings used in the description of the embodiments of the present application will be briefly introduced below. It is apparent that the accompanying drawings in the following description are only some embodiments of the present application, and other drawings can be obtained by those of ordinary skill in the art from the provided drawings without creative efforts.

FIG. 1 is a schematic diagram of a sectional structure of a display panel according to some embodiments of the present application;

FIG. 2 is a schematic diagram of a sectional structure of a display panel according to some embodiments of the present application;

FIG. 3 is a schematic diagram of a partial plane structure of a display panel according to some embodiments of the present application;

FIG. 4 is a schematic diagram of a sectional structure of a display panel according to some embodiments of the present application;

FIG. 5 is a schematic diagram of a sectional structure of a display panel according to some embodiments of the present application;

FIG. 6 is a schematic diagram of a partial plane structure of a display panel according to some embodiments of the present application;

FIG. 7 is a schematic diagram of a partial plane structure of a display panel according to some embodiments of the present application;

FIG. 8 is a schematic diagram of a sectional structure of a display panel according to some embodiments of the present application;

FIG. 9 is a schematic diagram of a plane structure of a display panel according to some embodiments of the present application;

FIG. 10 is a schematic diagram of a partial plane structure of a display panel according to some embodiments of the present application;

FIG. 11 is a schematic sectional view of a display panel according to an embodiment of the present application;

FIG. 12 is a partial sectional view of a display panel in another embodiment;

FIG. 13 is a schematic top view of a display panel according to an embodiment of the present application;

FIG. 14 is a partial top view of a display panel in another embodiment;

FIG. 15 is a partial top view of a display panel in yet another embodiment;

FIG. 16 is a partial sectional view of a display panel in yet another embodiment;

FIG. 17 is a partial sectional view of a display panel in still another embodiment; and

FIG. 18 is a schematic flowchart of a method for manufacturing a display panel according to an embodiment of the present application.

### REFERENCE NUMERALS

100. display panel; 1. substrate; 11. base; 12. driving circuit layer; 121. active layer; 122. gate; 123. drain; 124. source; 125. first plate; 126. second plate; 127. first conductive structure; 13. second planarization layer;
2. isolation structure; 21. first isolation portion; 211. conductive layer; 2111. main body portion; 2112. frame portion; 22. second isolation portion; 23. defining opening; 24. light-transmitting opening; 210. first conductive layer; 220. second conductive layer; 230. third layer;
3. light-emitting functional layer; 31. light-emitting portion; 311. red light-emitting portion; 312. green light-emitting portion; 313. blue light-emitting portion; 700. first electrode layer;
320. first electrode layer; 32. first electrode; 330. second electrode layer; 33. second electrode; 4. touch layer; 41. first touch electrode layer; 411. first touch electrode; 412. second touch electrode;
42. second touch electrode layer;
5. light-transmitting shielding layer; 51. first via; 410. light-transmitting blocking portion;
6. first planarization layer; 61. second opening; 600. transparent filling portion;
71. first encapsulation layer; 711. first opening; 72. second encapsulation layer; 73. touch buffer layer; 74. touch encapsulation layer; 75. optically clear adhesive (OCA) layer; 76. third encapsulation layer; 761. encapsulation portion;
9. pixel defining layer; 91. pixel defining portion; 92. pixel opening; 830. accommodating opening;
900. encapsulation layer; AA. display region; NA. non-display region; SA. light-sensing region; X. first direction; Y second direction; Z. third direction.

### DETAILED DESCRIPTION

Features and exemplary embodiments in various aspects of the present application will be described in detail below. In order to make the objectives, technical solutions, and advantages of the present application clearer, the present application will be described in further detail below with reference to the accompanying drawings and specific embodiments. It should be understood that the specific embodiments described herein are only configured to explain the present application, rather than to limit the present application. For those skilled in the art, the present application can be implemented without some of these specific details. The following description of the embodiments is merely to provide a better understanding of the present application by illustrating the examples of the present application.

It is to be noted that the relationship terms used herein, such as first and second, are only used to distinguish one entity or operation from another entity or operation, but do not necessarily require or imply that there is such an actual relationship or order between these entities or operations. Moreover, the terms “include,” “comprise,” or any variants thereof are intended to cover a non-exclusive inclusion, such that processes, methods, articles, or devices, including a series of elements, include not only those elements that have been listed, but also other elements that have not specifically been listed or the elements inherent to these processes, methods, articles, or devices. Without further limitations, elements defined by the wording “comprise(s)/include(s) a/an . . . ” do not exclude additional identical elements in the processes, methods, articles, or devices including the listed elements.

It should be understood that when structure of a component is described, a layer or region being arranged “above” or “on” another layer or region means that the layer or region is directly on the another layer or region or that there is still another layer or region between the layer or region and the another layer or region. Moreover, if the component is flipped, the layer or region will be located “below” or “under” the another layer or region.

Alight-emitting functional layer, a driving circuit layer, and a touch layer are arranged in a display panel. The driving circuit layer is configured to drive the light-emitting functional layer to emit light for display. The touch layer is configured to realize touch and control of the display panel by a user. The touch layer and the driving circuit layer are disposed on two opposite sides of the light-emitting functional layer respectively. Parasitic capacitance is generated between the touch layer and a driving circuit, causing radio frequency interference between them and reducing image quality of display on the display panel.

To solve the above problems, embodiments of the present application provide a display panel and a display apparatus. Various embodiments of the display panel and the display apparatus will be described below with reference to the accompanying drawings.

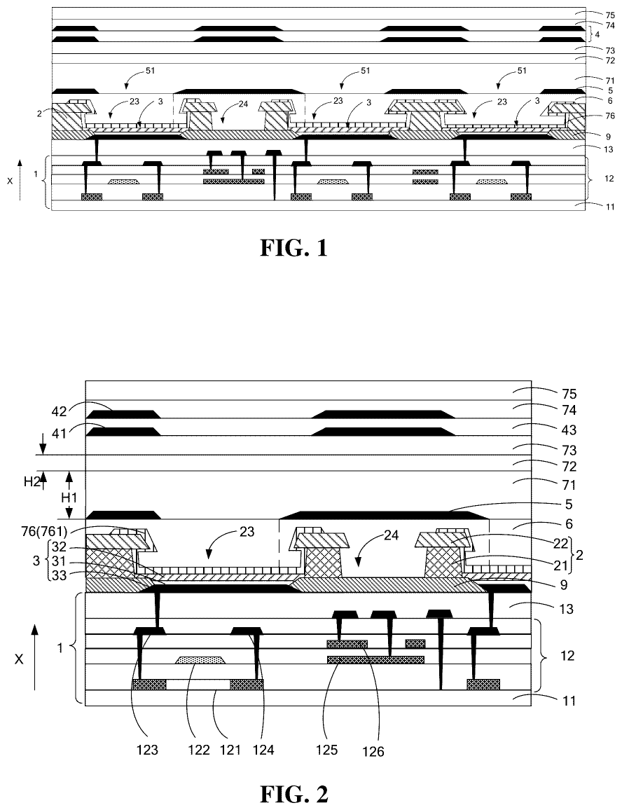

In a first aspect of the present application, a display panel 100 is provided. As shown in FIG. 1 and FIG. 2, the display panel 100 includes a substrate 1, an isolation structure 2, a light-emitting functional layer 3, a touch layer 4, and a light-transmitting shielding layer 5. The isolation structure 2 is arranged on a side of the substrate 1, and the isolation structure 2 is configured to enclose a plurality of defining openings 23 and a plurality of light-transmitting openings 24. The light-emitting functional layer 3 includes a plurality of light-emitting portions 31. The light-emitting portion 31 is at least partially arranged in the defining opening 23. The touch layer 4 is arranged on a side of the isolation structure 2 facing away from the substrate 1. The light-transmitting shielding layer 5 is arranged between the isolation structure 2 and the touch layer 4. Along a direction from the touch layer 4 to the substrate 1, an orthographic projection of the light-transmitting shielding layer 5 on the substrate 1 is at least partially overlapped with an orthographic projection of the light-transmitting opening 24 on the substrate 1.

The display panel 100 provided in this embodiment of the present application may be an OLED display panel 100.

In the display panel 100 provided in this embodiment of the present application, the substrate 1 may provide support for the isolation structure 2 and also provide electrical signals for the light-emitting functional layer 3 and the touch layer 4. The substrate 1 is arranged in a variety of manners. In some embodiments, the substrate 1 may include a base 11 and a driving circuit layer 12 arranged on the base 11. The driving circuit layer 12 may include a pixel driving circuit, a plurality of conductive connected structures arranged in stack, and the like. For example, the pixel driving circuit arranged on the driving circuit layer 12 includes a transistor and a storage capacitor. The transistor includes an active layer 121, a gate 122, a drain 123, and a source 124. The storage capacitor includes a first plate 125 and a second plate 126. As an example, the gate 122 and the first plate 125 may be located on a same conductive layer, the second plate 126 may be located on another conductive layer, and the drain 123 and the source 124 may be located on still another conductive layer.

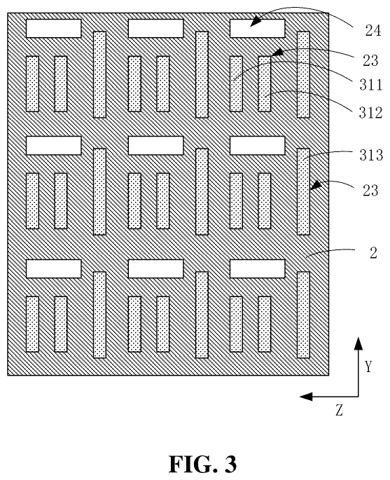

Referring to FIG. 3, the isolation structure 2 is configured to enclose a plurality of defining openings 23 and a plurality of light-transmitting openings 24, and the adjacent defining opening 23 and light-transmitting opening 24 are separated by the isolation structure 2. The number of the defining openings 23 may be in one-to-one correspondence to the number of the light-emitting portions 31. Light incident on the display panel 100 from one side of the display panel 100 may be emitted from the other side of the display panel 100 through the light-transmitting opening 24. A light sensor located on a side of the display panel 100 receives the light to perform photoelectric conversion. The light sensor may specifically be an infrared sensor, a camera, or the like.

The plurality of light-emitting portion 31 may be light-emitting portions 31 that can emit light in different colors, which may be, for example, a red light-emitting portion 311 that can emit red light, a green light-emitting portion 312 that can emit green light, and a blue light-emitting portion 313 that can emit blue light. The numbers of the defining openings 23 and the light-transmitting openings 24 may be determined as required. For example, in the embodiment shown in FIG. 3, the red light-emitting portion 311, the green light-emitting portion 312, and the blue light-emitting portion 313 are respectively located in three defining openings 23 and form a pixel light-emitting group. One pixel light-emitting group corresponds to one light-transmitting opening 24 to form repeating units, and the repeating units are arranged in an array along a second direction Y and a third direction Z. In another embodiment, a plurality of pixel light-emitting groups correspond to one light-transmitting opening 24 to form repeating units, and the repeating units are arranged in an array along the second direction Y and the third direction Z.

The touch layer 4 enables the display panel 100 to perform a touch and control operation, and the touch layer 4 may be arranged on a light-emitting side of the light-emitting functional layer 3. In order to prevent an influence of the touch layer 4 on display of the light-emitting functional layer 3, the touch layer 4 may be made of a light-transmitting material. The touch layer 4 may include touch electrodes spaced apart, and adjacent touch electrodes cooperate with each other to form a touch capacitor. A touch position of the user on the display panel 100 may be determined by analyzing varying electrical signals in the touch capacitor.

The light-transmitting shielding layer 5 may be made of a light-transmitting conductive material. The light-transmitting conductive material is, for example, indium oxide-tin oxide-based oxide (ITO), indium oxide-zinc oxide-based oxide (IZO), or the like. Light emitted by the light-emitting portion 31 may be transmitted through the light-transmitting shielding layer 5, and the light incident on the display panel 100 may be transmitted through the light-transmitting shielding layer 5. The orthographic projection of the light-transmitting shielding layer 5 on the substrate 1 is at least partially overlapped with the orthographic projection of the light-transmitting opening 24 on the substrate 1. That is, the light-transmitting shielding layer 5 blocks at least part of the light-transmitting opening 24. Since the light-transmitting shielding layer 5 blocks at least part of the light-transmitting opening 24, radio frequency between the touch layer 4 and the driving circuit layer 12 that may pass through the light-transmitting opening 24 may be blocked by the light-transmitting shielding layer 5. Optionally, the orthographic projection of the light-transmitting opening 24 on the substrate 1 is located within the orthographic projection of the light-transmitting shielding layer 5 on the substrate 1, that is, the light-transmitting shielding layer 5 blocks the light-transmitting opening 24 to improve the capability of the light-transmitting shielding layer 5 to block the radio frequency between the touch layer 4 and the driving circuit layer 12 that may pass through the light-transmitting opening 24.

The display panel 100 provided in the present application may further include a cover plate covering a side of the touch layer 4 facing away from the substrate 1, an OCA layer 75 located between the cover plate and the touch layer 4, a touch encapsulation layer 74 encapsulating the touch layer 4, and the like.

In the embodiments provided in the present application, the light-transmitting openings 24 are provided, so as to increase light transmittance of the display panel 100; the light-transmitting shielding layer 5 is arranged between the isolation structure 2 and the touch layer 4, and the light-transmitting shielding layer 5 is arranged to block at least part of the light-transmitting openings 24, so that radio frequency between the touch layer 4 and the driving circuit layer 12 that may pass through the light-transmitting openings 24 can be blocked by the light-transmitting shielding layer 5, which prevents or reduces radio frequency interference between the touch layer 4 and the driving circuit layer 12 and improve image quality of display on the display panel 100.

In some embodiments, the display panel 100 further includes a first planarization layer 6, the light-transmitting shielding layer 5 is arranged on a side of the first planarization layer 6 facing away from the substrate 1, and the first planarization layer 6 is at least partially arranged within the light-transmitting opening 24.

The first planarization layer 6 is at least partially arranged in the light-transmitting opening 24 by covering a side of the isolation structure 2 facing away from the substrate 1, so that the first planarization layer 6 distributed in the light-transmitting opening 24 may support a layer structure located on the side of the first planarization layer 6 facing away from the substrate 1 to prevent collapse of the layer structure at the light-transmitting opening 24.

In some embodiments, the display panel 100 further includes a first planarization layer 6, the first planarization layer 6 covers a side of the isolation structure 2 facing away from the substrate 1, and the first planarization layer 6 covers a side of the light-emitting functional layer 3 facing away from the substrate 1.

Since a surface of the isolation structure 2 facing away from the substrate 1 and a surface of the light-emitting functional layer 3 facing away from the substrate 1 are uneven, by covering the side of the isolation structure 2 facing away from the substrate 1 and covering the side of the light-emitting functional layer 3 facing away from the substrate 1, the first planarization layer 6 has a flat surface at an end facing away from the substrate 1, to facilitate arrangement of other functional layers on the first planarization layer 6. The first planarization layer 6 may be an organic film layer.

In some embodiments, the light-transmitting shielding layer 5 is arranged on the side of the first planarization layer 6 facing away from the substrate 1.

Compared with direct arrangement of the light-transmitting shielding layer 5 on the isolation structure 2 and the light-emitting functional layer 3, the first planarization layer 6 have a flat surface on a side facing away from the substrate 1, which may prevent or reduce breakage of the disposed light-transmitting shielding layer 5, making the light-transmitting shielding layer 5 complete and reliable.

In some embodiments, the display panel 100 further includes a first encapsulation layer 71, the first encapsulation layer 71 is arranged between the first planarization layer 6 and the touch layer 4, and the first encapsulation layer 71 covers a side of the light-transmitting shielding layer 5 facing away from the substrate 1.

The first encapsulation layer 71 may include an organic material and/or an inorganic material. The first encapsulation layer 71 may improve a barrier capability of the display panel 100 against water and oxygen, and prevent an influence on light emission of the light-emitting portion 31 caused by entry of external water and oxygen into the light-emitting functional layer 3.

In some embodiments, the display panel 100 further includes a second encapsulation layer 72, and the second encapsulation layer 72 is arranged between the first encapsulation layer 71 and the touch layer 4.

The second encapsulation layer 72 may include an organic material and/or an inorganic material. The first encapsulation layer 71 and the second encapsulation layer 72 may be made of different materials, so that the first encapsulation layer 71 and the second encapsulation layer 72 may have different properties to improve a capability of the display panel 100 to resist water and oxygen.

In some embodiments, the first encapsulation layer 71 is an organic material layer, and the second encapsulation layer 72 is an inorganic material layer.

Compared with the organic material layer, the inorganic material layer has a better capability to block water and oxygen. Compared with the inorganic material layer, the organic material layer has better flexibility and good film-forming properties. The light-emitting functional layer 3 is encapsulated through both of the organic material layer and the inorganic material layer to improve a comprehensive capability of the display panel 100 to resist water and oxygen.

In some embodiments, a thickness of the first encapsulation layer 71 along a thickness direction of the display panel 100 is H1, and a thickness of the second encapsulation layer 72 along the thickness direction of the display panel 100 is H2, where H1>H2.

The first planarization layer 6, the first encapsulation layer 71, and the second encapsulation layer 72 each may provide a flat surface to form the light-transmitting shielding layer 5. However, since H1>H2, the light-transmitting shielding layer 5 is arranged on a side of the first encapsulation layer 71 close to the substrate 1, so that the light-transmitting shielding layer 5 and the touch layer 4 are separated by the first encapsulation layer 71 and the second encapsulation layer 72 between them, thereby increasing a spacing distance between the light-transmitting shielding layer 5 and the touch layer 4, and preventing or reducing an influence of the light-transmitting shielding layer 5 on the implementation of function of the touch layer 4.

In some embodiments, the display panel 100 further includes a third encapsulation layer 76, the third encapsulation layer 76 is arranged between the first planarization layer 6 and the light-emitting functional layer 3, and the third encapsulation layer 76 covers the light-emitting portion 31.

The display panel 100 may further include a first electrode 32 and a second electrode 33 arranged on two opposite sides of the light-emitting portion 31. The first electrode 32, the light-emitting portion 31, and the second electrode 33 are stacked along a direction from the touch layer 4 to the substrate 1. One of the first electrode 32 and the second electrode 33 may be a cathode, and the other may be an anode. Each of the first electrode 32 and the second electrode 33 is connected to the light-emitting portion 31 and configured to drive the light-emitting portion 31 to emit light. The third encapsulation layer 76 may cover a side of the first electrode 32 facing away from the substrate 1. The third encapsulation layer 76 may reduce or prevent entry of water and oxygen into the light-emitting portion 31 and prolong a service life of the light-emitting portion 31.

A material of the third encapsulation layer 76 may be the same as a material of the first encapsulation layer 71 or the second encapsulation layer 72 to simplify the manufacturing process.

In some embodiments, the third encapsulation layer 76 includes a plurality of encapsulation portions 761, at least part of the encapsulation portions 761 are located within the defining openings 23 and cover the light-emitting portions 31. Edges of the encapsulation portions 761 are in contact with the isolation structure 2.

The encapsulation portions 761 may be arranged in one-to-one correspondence to the light-emitting portions 31. That is, one encapsulation portion 761 is configured to encapsulate one light-emitting portion 31. The encapsulation portions 761 may be entirely arranged in the defining openings 23 or partially extend to the outside of the defining openings 23. The edges of the encapsulation portions 761 are in contact with the isolation structure 2 to prevent or reduce formation of gaps between the encapsulation portions 761 and the isolation structure 2 through which water and oxygen may pass.

Since the light-emitting portion 31 is not arranged in the light-transmitting opening 24, the third encapsulation layer 76 may not be arranged in the light-transmitting opening 24 to reduce or prevent unnecessary refraction of the light incident on the light-transmitting opening 24 in the light-transmitting opening 24, increasing light transmittance of the light-transmitting opening 24.

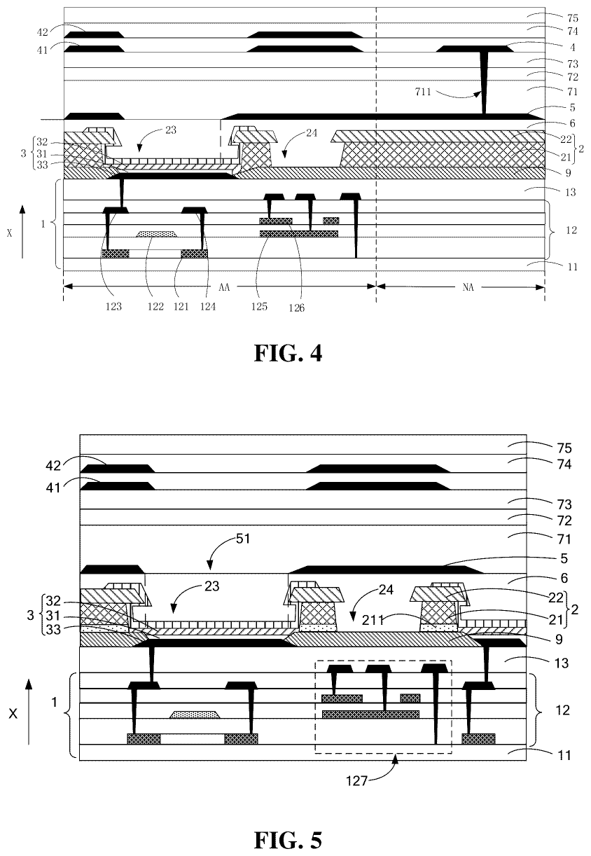

Referring to FIG. 4, in some embodiments, at least part of the touch layer 4 is electrically connected to the light-transmitting shielding layer 5.

The touch layer 4 is arranged to be electrically connected to the light-transmitting shielding layer 5, so that the touch layer 4 and the light-transmitting shielding layer 5 may keep their potentials close to or consistent with each other, thereby preventing or reducing generation of parasitic capacitance between the touch layer 4 and the light-transmitting shielding layer 5 to some extent.

In some embodiments, the display panel further includes a first encapsulation layer 71, the first encapsulation layer 71 covers a side of the light-transmitting shielding layer 5 facing away from the substrate 1, the first encapsulation layer 71 includes a first opening 711, the light-transmitting shielding layer 5 is exposed by the first opening 711, and at least part of the touch layer 4 is electrically connected to the light-transmitting shielding layer 5 through the first opening 711.

A portion of the touch layer 4 is formed in the first opening 711 and is electrically connected to the light-transmitting shielding layer 5, so that the touch layer 4 and the light-transmitting shielding layer 5 can be electrically connected. The portion of the touch layer 4 may specifically be a ground terminal (TSP GND) of the touch layer 4.

In some embodiments, the display panel 100 includes a display region AA and a non-display region NA connected to each other, and the first opening 711 is located in the non-display region NA.

The first opening 711 is arranged in the non-display region NA, so that a junction between the light-transmitting shielding layer 5 and the touch layer 4 is located in the non-display region. In a case where other layer structures are arranged between the touch layer 4 and the light-transmitting shielding layer 5, a via running through the layer structure is arranged to realize a via connection between the touch layer 4 and the light-transmitting shielding layer 5. In the embodiment as shown in FIG. 4, the display panel 100 further includes a second encapsulation layer 72 and a touch buffer layer 73, the light-transmitting shielding layer 5, the first encapsulation layer 71, the second encapsulation layer 72, the touch buffer layer 73, and the touch layer 4 are sequentially stacked along a first direction X, a via running through the first encapsulation layer 71, the second encapsulation layer 72, and the touch buffer layer 73 is arranged, the first opening 711 may be a section of the via, and the touch layer 4 and the light-transmitting shielding layer 5 are in the via connection through the via.

Referring to FIG. 5, in some embodiments, the display panel 100 further includes a first planarization layer 6, the first encapsulation layer 71 is arranged between the first planarization layer 6 and the touch layer 4, the light-transmitting shielding layer 5 is arranged on a side of the first planarization layer 6 facing away from the substrate 1, the light-transmitting shielding layer 5 further includes a plurality of first vias 51, and the first planarization layer 6 and the first encapsulation layer 71 are in contact through the first vias 51.

The first planarization layer 6 and the first encapsulation layer 71 are in contact through the first via 51 so that the first via 51 may be used as a ventilation hole. When the display panel 100 is in a high-temperature environment, gas released from some materials in the display panel 100 may be discharged through the ventilation hole to prevent bubbling of the film layer. Some of the materials in the display panel 100 may be organic material of the first planarization layer 6. When the first planarization layer 6 is in a high-temperature environment, gas released from the organic material in the first planarization layer 6 may be discharged to the first encapsulation layer 71 through the ventilation hole, and then discharged outwards through the first encapsulation layer 71 to prevent bubbling of the first planarization layer 6.

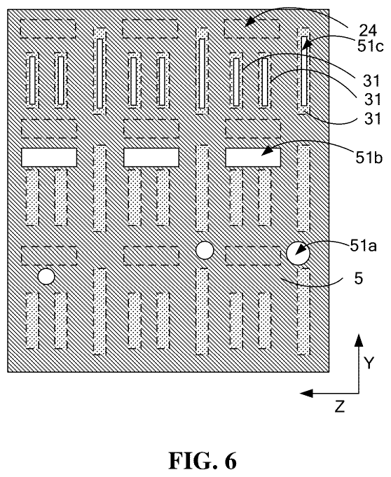

Referring to FIG. 6, the first vias 51 may be distributed regularly or randomly. The shape and size of the first via 51 may be determined as required. For example, a first via 51a shown in FIG. 6 is a via having a circular cross section, and a plurality of first vias 51a are randomly distributed. In another example, a first via 51b shown in FIG. 6 is a via having a rectangular cross section, and a plurality of first vias 51b are in one-to-one correspondence to a plurality of pixel light-emitting groups to form repeating units, and the light-transmitting shielding layer 5 covers the pixel light-emitting groups. In yet another example, a first via 51c shown in FIG. 6 is a via having a rectangular cross section. A plurality of first vias 51c are in one-to-one correspondence to a plurality of pixel light-emitting groups to form repeating units, and the light-emitting portion 31 is exposed by the first via 51.

Referring to FIG. 5 and FIG. 7, in some embodiments, an orthographic projection of the light-emitting portion 31 on the light-transmitting shielding layer 5 is at least partially overlapped with the first via 51, so that part of the light emitted by the light-emitting portion 31 may be directly emitted outwards through the first via 51 without passing through the light-transmitting shielding layer 5. Optionally, the orthographic projection of the light-emitting portion 31 on the light-transmitting shielding layer 5 falls within the first via 51.

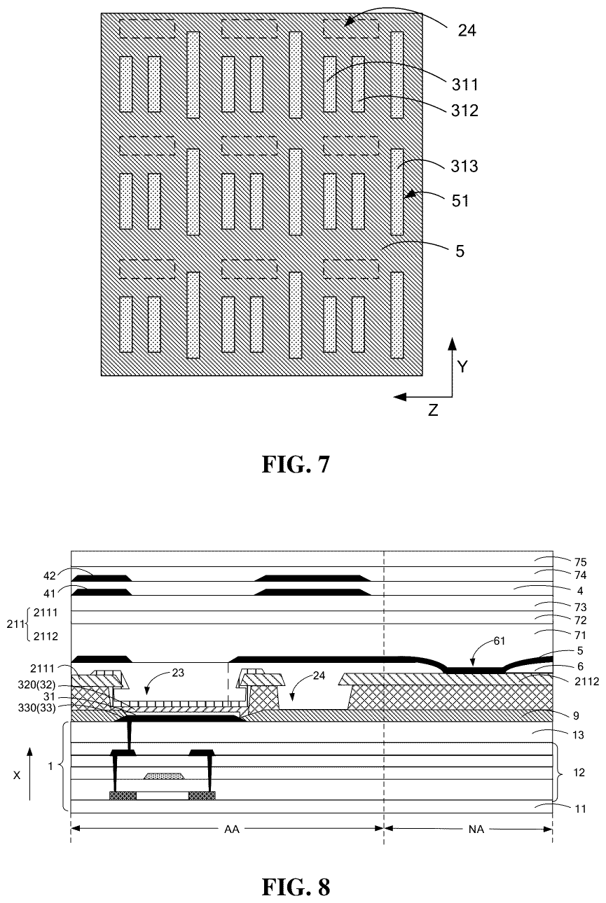

Referring to FIG. 8, in some embodiments, the display panel 100 further includes a first electrode layer 320, the first electrode layer 320 is located on a side of the light-emitting portion 31 facing away from the substrate 1, the first electrode layer 320 includes a first electrode 32 in the defining opening 23, and the first electrode 32 is electrically connected to the light-transmitting shielding layer 5.

The first electrode 32 is arranged to be electrically connected to the light-transmitting shielding layer 5, so that the light-emitting functional layer 3, the first electrode layer 320, and the light-transmitting shielding layer 5 may keep their potentials close to or consistent with each other, thereby preventing or reducing generation of parasitic capacitance between the light-emitting functional layer 3 and the light-transmitting shielding layer 5 to some extent.

In some embodiments, the display panel 100 further includes a first planarization layer 6 and a first electrode layer 320, the light-transmitting shielding layer 5 is arranged on a side of the first planarization layer 6 facing away from the substrate 1, the first electrode layer 320 is located on a side of the light-emitting portion 31 facing away from the substrate 1, the first electrode layer 320 includes a first electrode in the defining opening 23, the isolation structure 2 includes a conductive layer 211, edges of the first electrode 32 are overlapped with the conductive layer 211, the first planarization layer 6 includes a second opening 61, the conductive layer 211 is exposed by the second opening 61, and a portion of the light-transmitting shielding layer 5 is arranged in the second opening 61 and is electrically connected to the conductive layer 211.

The first electrode 32 may be a cathode or an anode. The first electrode 32 is connected to the light-emitting portion 31 to drive the light-emitting portion 31 to emit light. The edges of the first electrode 32 are overlapped with the conductive layer 211, so that the conductive layer 211 may supply power to the first electrode 32 and make the adjacent first electrodes 32 to be electrically conductive, thereby forming a surface electrode electrically conductive throughout the surface.

When the first electrode 32 is overlapped with the conductive layer 211 to form the surface electrode, the touch layer 4 and the driving circuit layer 12 may be blocked by the surface electrode. A portion between the touch layer 4 and the driving circuit layer 12 that is not blocked at the light-transmitting opening 24 by the surface electrode may be blocked by the light-transmitting shielding layer 5.

A portion of the light-transmitting shielding layer 5 is formed in the second opening 61 and is electrically connected to the conductive layer 211, so that the conductive layer 211 and the light-transmitting shielding layer 5 can be electrically connected. The conductive layer 211 exposed by the second opening 61 may be a power supply voltage terminal (ELVSS) or a common ground voltage terminal (ELVDD) electrically connected to the light-emitting functional layer 3.

In some embodiments, the display panel 100 includes a display region AA and a non-display region NA connected to each other, the conductive layer 211 includes a main body portion 2111 located in the display region AA and a frame portion 2112 located in the non-display region NA, the second opening 61 is located in the non-display region NA, the light-transmitting shielding layer 5 is spaced apart from the main body portion 2111, and the light-transmitting shielding layer 5 is connected to the frame portion 2112 exposed to the second opening 61.

The light-emitting portion 31 may be arranged only in the display region AA. A portion of the light-transmitting shielding layer 5 located in the display region AA is spaced apart from the main body portion 2111, and a portion located in the non-display region NA may be electrically connected to the frame portion 2112 through the second opening 61. The second opening 61 is arranged in the non-display region NA, and the light-transmitting shielding layer 5 is connected to the frame portion 2112 exposed to the second opening 61, so that a junction between the light-transmitting shielding layer 5 and the conductive layer 211 is located in the non-display region NA. The light-transmitting shielding layer 5 may be arranged in a planar shape. The light-transmitting shielding layer 5 is electrically connected to the conductive layer 211 at one position, or is electrically connected to the touch layer 4 at one position, so that the entire light-transmitting shielding layer 5 can be powered on.

In some embodiments, the display panel 100 further includes a second electrode layer 330, the second electrode layer 330 includes a plurality of second electrodes 33, and the plurality of second electrodes 33 are located on a side of the light-emitting portion 31 close to the substrate 1. One of the first electrode 32 and the second electrode 33 may serve as an anode electrode and the other may serve as a cathode electrode. The first electrode 32, the light-emitting portion 31, and the second electrode 33 may be sequentially stacked and contacted to achieve electrical conduction between the first electrode 32, the light-emitting portion 31, and the second electrode 33. Optionally, the first electrode 32 is an anode electrode, and the second electrode 33 is a cathode electrode.

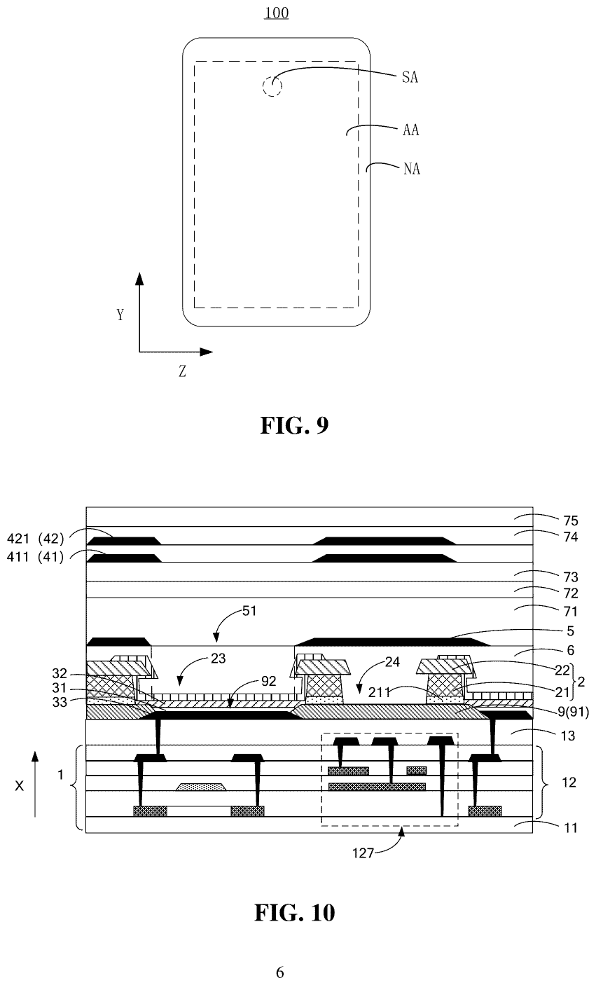

Referring to FIG. 9 and FIG. 10, in some embodiments, the light-transmitting opening 24 is located between the adjacent defining openings 23.

A plurality of light-transmitting openings 24 may be uniformly distributed in the isolation structure 2, or may be aggregated and distributed in a partial area of the isolation structure 2. In some embodiments, the display panel 100 has a display region AA, and at least part of the display region AA is reused as a light-sensing region SA. That is, the light-sensing region SA is located in the display region AA. At least part of the display region AA is used for both image display and light sensing. The light-transmitting opening 24 is arranged in the light-sensing region SA to increase light transmittance of the light-sensing region SA, so that one side of the light-sensing region SA is suitable for placement of a light sensor. Light incident on the display panel 100 from one side of the display panel 100 may be emitted from the other side of the display panel 100 through the light-transmitting opening 24. The light sensor located on one side of the display panel 100 receives the light to perform photoelectric conversion. The light sensor may specifically be an infrared sensor, a camera, or the like.

Optionally, the isolation structure 2 is grid-like, the defining openings 23 are arranged in an array, and the light-transmitting opening 24 is arranged between the adjacent defining openings 23.

In some embodiments, along a direction from the touch layer 4 to the substrate 1, an orthographic projection of the light-transmitting shielding layer 5 on the substrate 1 is at least partially overlapped with an orthographic projection of the isolation structure 2 on the substrate 1.

The light-transmitting shielding layer 5 blocks the light-transmitting opening 24 and also blocks at least part of the isolation structure 2 to increase a blocking area of the light-transmitting shielding layer 5 between the touch layer 4 and the substrate 1 that can realize a blocking function.

In some embodiments, the isolation structure 2 includes a first isolation portion 21 and a second isolation portion 22 stacked on the first isolation portion 21, the first isolation portion 21 is arranged on a side of the second isolation portion 22 close to the substrate 1, and an orthographic projection of the first isolation portion 21 on the substrate 1 is located within an orthographic projection of the second isolation portion 22 on the substrate 1.

The isolation structure 2 is configured to enclose a defining opening 23 to limit a setting range of the light-emitting functional layer 3. The isolation structure 2 includes a first isolation portion 21 and a second isolation portion 22 stacked on the first isolation portion 21, and an orthographic projection of the first isolation portion 21 on the substrate 1 is located within an orthographic projection of the second isolation portion 22 on the substrate 1, so that an area of a cross section at an end of the isolation structure 2 away from the substrate 1 is larger, and an area of a cross section at an end of the isolation structure 2 close to the substrate 1 is smaller. Along a direction from the isolation structure 2 to the substrate 1 (the direction X), the second isolation portion 22 completely blocks the first isolation portion 21.

When the light-emitting portion 31 is disposed, a light-emitting material A used to manufacture the light-emitting portion 31 may cover the isolation structure 2 based on an evaporation technology. Since the second isolation portion 22 blocks the first isolation portion 21, the light-emitting material A used to manufacture the light-emitting portion 31 has a large drop at an edge of the second isolation portion 22, and it is difficult to connect the light-emitting material A falling within the defining opening 23 with the light-emitting material A falling on the second isolation portion 22, thereby causing breakage and forming the light-emitting material A spaced apart in adjacent defining openings 23. The light-emitting material A falling on the second isolation portion 22 may be removed as required. Compared with the related art in which the light-emitting functional layer 3 is evaporated and disposed through a mask, in the present application, the first isolation portion 21 and the second isolation portion 22 are arranged, so that the light-emitting portion 31 located in the defining opening 23 can be disposed without a metal mask, thereby saving the cost of manufacturing the metal mask. Compared with evaporation and manufacturing of the light-emitting functional layer 3 by manufacturing a high-precision metal mask, it is easier to directly manufacture the high-precision isolation structure 2, so that the structure of the display panel 100 provided in the present application has low requirements on the manufacturing process, and the disposed display panel 100 has good consistency. The light-emitting material A may be a complex containing an indium element.

In some embodiments, an area of an orthographic projection of a surface of the second isolation portion 22 facing away from the substrate 1 on the substrate 1 is less than an area of an orthographic projection of a surface of the second isolation portion 22 close to the substrate 1 on the substrate 1.

The second isolation portion 22 extends outwards by a predetermined distance relative to the first isolation portion 21, that is, the area of the orthographic projection of the surface of the second isolation portion 22 facing away from the substrate 1 on the substrate 1 is less than the area of the orthographic projection of the surface of the second isolation portion 22 close to the substrate 1 on the substrate 1, so that the second isolation portion 22 has an inclined slope structure so as to define a pattern of the light-emitting functional layer 3 through the second isolation portion 22.

In some embodiments, an area of a cross section of the second isolation portion 22 gradually decreases in a direction away from the substrate 1.

Optionally, the cross section of the second isolation portion 22 is a trapezoid with a bottom edge facing the substrate 1, so that the second isolation portion 22 has a sloped surface, which is conducive to disconnection of the manufacturing material at a partition edge, forming a state in which part of the manufacturing material is located on the second isolation portion 22 and part of the manufacturing material is located in the defining opening 23.

In some embodiments, an area of an orthographic projection of a surface of the first isolation portion 21 facing away from the substrate 1 on the substrate 1 is less than the area of the orthographic projection of the surface of the second isolation portion 22 close to the substrate 1 on the substrate 1.

That is, the second isolation portion 22 protrudes relative to the first isolation portion 21 to limit patterns of the first electrode 32 and the light-emitting functional layer 3 through the second isolation portion 22. An area of the second isolation portion 22 is greater than the first isolation portion 21 and completely covers the first isolation portion 21. In this case, the first isolation portion 21 is recessed relative to the second isolation portion 22 in a direction away from the defining opening 23. When the second electrode 33 is disposed, the second electrodes 33 have a large drop at the edge of the isolation structure 2, and the first isolation portion 21 is concavely arranged. It is difficult to connect the second electrodes 33 on an outer side of the isolation structure 2, thereby resulting in breakage and forming mutually isolated second electrodes 33.

In some embodiments, an area of an orthographic projection of a surface of the second isolation portion 22 facing away from the substrate 1 on the substrate 1 is less than an area of an orthographic projection of a surface of the second isolation portion 22 close to the substrate 1 on the substrate 1.

The conductive layer 211 in the isolation structure 2 may be located in the first isolation portion 21 or the second isolation portion 22, which may be selected by those skilled in the art as required. The conductive layer 211 may be a single-layer metal structure. For example, the conductive layer 211 may include only one layer of aluminum. Alternatively, according to an actual requirement, the conductive layer 211 may alternatively include a multi-layer metal structure. For example, the conductive layer 211 may include a first sub-portion and a second sub-portion that are stacked. The first sub-portion includes molybdenum and/or titanium, and the second sub-portion includes aluminum.

Optionally, etching rates of molybdenum and titanium are low, so that the first sub-portion extends outwards relative to the second sub-portion, and the cross section of the first isolation portion 21 is trapezoidal to facilitate overlapping with the first electrode 32 formed by evaporation. When both the first sub-portion and the second isolation portion 22 are made of titanium metal, the manufacturing process can be simplified.

In some embodiments, an area of a cross section of the first isolation portion 21 gradually decreases in the direction away from the substrate 1.

The cross section of the first isolation portion 21 may be trapezoidal, increasing a size of the defining opening 23. A cross-sectional shape of the first isolation portion 21 may be a regular trapezoid, which can, on the one hand, firmly support the second isolation portion 22, and on the other hand, make a contact surface area between the first sub-portion and the second isolation portion 22 smaller, thereby realizing concave arrangement of the first isolation portion 21 relative to the second isolation portion 22 in a direction facing away from a central axis of the defining opening 23 and facilitating disconnection of the second electrode 33 and the light-emitting functional layer 3 at the isolation structure 2.

In such optional embodiments, in order to obtain the first isolation portion 21 concavely arranged, during etching, the second sub-portion has a faster etching rate relative to the first sub-portion and/or the second isolation portion 22, thereby forming the concave first isolation portion 21. Since the etching rate of the second sub-portion is faster, more waste generated by the etching can easily enter other positions of the display panel 100, thereby causing adverse effects. The orthographic projection of the second sub-portion on the substrate 1 is located within the orthographic projection of the first sub-portion on the substrate 1 so that the second sub-portion can be better supported on the first sub-portion and etching waste generated falls on the first sub-portion for easy cleaning.

Optionally, an orthographic projection of the second isolation portion 22 on the substrate 1 is overlapped with the orthographic projection of the first sub-portion on the substrate 1. The first sub-portion and the second isolation portion 22 having a same area can be etched by using a same mask, which simplifies the manufacturing process.

In some embodiments, the display panel 100 further includes a second planarization layer 13, and the second electrode 33 is arranged on a side of the second planarization layer 13 facing away from the substrate 1. The second planarization layer 13 may planarize the driving circuit layer 12 so that the second electrode 33 may be formed on a plane provided by the second planarization layer 13, which is conducive to forming the required patterned second electrode 33. After the second electrode 33 is formed on the planarization layer, a material C used to manufacture the isolation structure 2 may cover the second electrode 33, and the material C is etched to form the defining opening 23 exposing the second electrode 33 and the light-transmitting opening 24 and to form the first isolation portion 21 and the second isolation portion 22. The light-emitting functional layer 3 may be disposed with reference to the foregoing manufacturing steps of the light-emitting functional layer 3. The material C may be any one or more of titanium, aluminum, and molybdenum.

The isolation structure 2 may be directly arranged on a side of the second planarization layer 13 facing away from the substrate 1, and the isolation structure 2 is supported by the second planarization layer 13.

In some embodiments, the display panel 100 further includes a pixel defining layer 9 arranged between the substrate 1 and the isolation structure 2, the pixel defining layer 9 includes a pixel opening 92, and an orthographic projection of the pixel opening 92 on the substrate 1 is located within a range of an orthographic projection of the defining opening 23 on the substrate 1.

The pixel defining layer 9 includes a pixel defining portion 91, and the pixel defining portion 91 is configured to enclose a pixel opening 92. The light-emitting portion 31 may be at least partially arranged within the pixel opening 92 to achieve light-emitting display of the display panel 100, and the pixel opening 92 may be arranged corresponding to the defining opening 23.

In some embodiments, the isolation structure 2 is arranged on a side of the pixel defining layer 9 facing away from the substrate 1, and the light-emitting functional layer 3 is at least partially arranged in the pixel opening 92.

The isolation structure 2 is arranged on the side of the pixel defining layer 9 facing away from the substrate 1, and an orthographic projection of the pixel opening 92 on the substrate 1 is located within an orthographic projection of the defining opening 23 on the substrate 1. The isolation structure 2 may be directly arranged on the side of the pixel defining layer 9 facing away from the substrate 1, and the isolation structure 2 is supported by the pixel defining layer 9. The orthographic projection of the pixel opening 92 on the substrate 1 may be located within the orthographic projection of the defining opening 23 on the substrate 1. An area of the defining opening 23 is larger than that of the pixel opening 92, which can reduce an influence of the isolation structure 2 on a light-emitting viewing angle of the light-emitting functional layer 3.

Optionally, a plurality of pixel openings 92 are provided, the plurality of pixel openings 92 are distributed at intervals, and the isolation structure 2 may be arranged on at least part of a pixel defining portion between two adjacent pixel openings 92. Optionally, the isolation structure 2 may be arranged around at least part of the pixel openings 92.

In some embodiments, the pixel defining layer 9 is exposed from the light-transmitting opening 24.

In some embodiments, the substrate 1 includes a base 11 and a driving circuit layer 12, the driving circuit layer 12 is arranged between the base 11 and the light-emitting functional layer 3, the driving circuit layer 12 includes a first conductive structure 127, and a projection of the first conductive structure 127 on the isolation structure 2 along the direction from the touch layer 4 to the substrate 1 at least partially falls into the light-transmitting opening 24.

The base 11 may be a silicon substrate, or a flexible base 11 such as polyimide may be used. The driving circuit layer 12 and a light-emitting device layer may include multiple layer structures, and each layer structure may be formed by chemical vapor deposition, evaporation, or the like. The direction shown by the axis X in FIG. 10 is a thickness direction of the display panel 100. Those skilled in the art may start from the base 11 and sequentially form each layer structure along the thickness direction X.

The first conductive structure 127 is a portion of the driving circuit layer 12 that is spaced apart from the touch layer 4 through the light-transmitting opening 24 along the thickness direction of the display panel 100. The light-transmitting shielding layer 5 may prevent or reduce radio frequencies generated between the first conductive structure 127 and the touch layer 4 to some extent.

The projection of the first conductive structure 127 on the isolation structure 2 along the direction from the touch layer 4 to the substrate 1 at least partially falls into the light-transmitting opening 24 to improve a blocking effect of the light-transmitting shielding layer 5 on the first conductive structure 127.

In some embodiments, the touch layer 4 includes a first touch electrode layer 41 and a second touch electrode layer 42, the first touch electrode layer 41 and the second touch electrode layer 42 are spaced apart along a direction from the substrate 1 to the touch layer 4, an orthographic projection of the first touch electrode layer 41 on the substrate 1 is at least partially overlapped with the orthographic projection of the isolation structure 2 on the substrate 1, and an orthographic projection of the second touch electrode layer 42 on the substrate 1 is at least partially overlapped with the orthographic projection of the isolation structure 2 on the substrate 1.

The first touch electrode layer 41 includes a plurality of first touch electrodes 411 spaced apart, the second touch electrode layer 42 includes a plurality of second touch electrodes 412 spaced apart, and the first touch electrodes 411 and the second touch electrodes 412 are spaced apart along the first direction X, thereby forming a touch capacitor. An insulating material is provided between the first touch electrode 411 and the second touch electrode 412 for insulation.

The orthographic projection of the first touch electrode layer 41 on the substrate 1 is at least partially overlapped with the orthographic projection of the isolation structure 2 on the substrate 1, and the orthographic projection of the second touch electrode layer 42 on the substrate 1 is at least partially overlapped with the orthographic projection of the isolation structure 2 on the substrate 1, so that at least part of the first touch electrode layer 41 or at least part of the second touch electrode layer 42 may be spaced apart from the driving circuit layer 12 by the isolation structure 2 to reduce undesired radio frequencies generated by the part of the first touch electrode layer 41 or the part of the second touch electrode layer 42 and the driving circuit layer 12.

In some embodiments, along the direction from the touch layer 4 to the substrate 1, the light-transmitting shielding layer 5 performs blocking between the first touch electrode layer 41 and the first conductive structure 127, and the light-transmitting shielding layer 5 performs blocking between the second touch electrode layer 42 and the first conductive structure 127, so as to improve a blocking effect of the light-transmitting shielding layer 5 between the first conductive structure 127 and the first touch electrode layer 41 and to improve a blocking effect of the light-transmitting shielding layer 5 between the first conductive structure 127 and the second touch electrode layer 42.

In some embodiments, along the direction from the touch layer 4 to the substrate 1, the orthographic projection of the first touch electrode layer 41 on the substrate 1 is not overlapped with an orthographic projection of the light-emitting portion 31 on the substrate 1, and the orthographic projection of the second touch electrode layer 42 on the substrate 1 is not overlapped with the orthographic projection of the light-emitting portion 31 on the substrate 1, to prevent an influence of the first touch electrode layer 41 or the second touch electrode layer 42 on light emission of the light-emitting portion 31.

In some embodiments, along the direction from the touch layer 4 to the substrate 1, the orthographic projection of the first touch electrode layer 41 on the substrate 1 is located within a range of an orthographic projection of the light-transmitting shielding layer 5 on the substrate 1, and the orthographic projection of the second touch electrode layer 42 on the substrate 1 is located within the range of the orthographic projection of the light-transmitting shielding layer 5 on the substrate 1, so that a side of the first touch electrode layer 41 close to the substrate 1 or a side of the second touch electrode layer 42 close to the substrate 1 can be blocked from radio frequencies by the light-transmitting shielding layer 5.

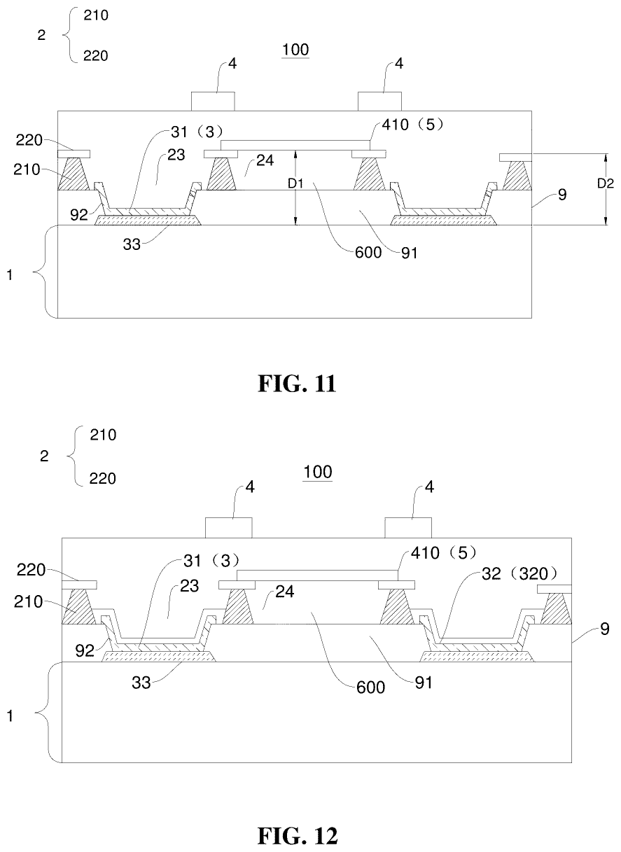

Referring to FIG. 11, FIG. 11 is a schematic sectional view of a display panel according to an embodiment of the present application.

As shown in FIG. 11, an embodiment of a first aspect of the present application further provides a display panel 100. The display panel 100 includes a substrate 1, an isolation structure 2, a light-emitting functional layer 3, a light-transmitting shielding layer 5, and a touch layer 4. The isolation structure 2 is located on one side of the substrate 1, and the isolation structure 2 is configured to enclose a defining opening 23 and a light-transmitting opening 24. The light-emitting functional layer 3 is located on one side of the substrate 1, and the light-emitting functional layer 3 includes a light-emitting portion 31 located in the defining opening 23. The light-transmitting shielding layer 5 is located on a side of the isolation structure 2 away from the substrate 1, the light-transmitting shielding layer 5 includes a light-transmitting blocking portion 410, and an orthographic projection of the light-transmitting opening 24 on the substrate 1 is located within an orthographic projection of the light-transmitting blocking portion 410 on the substrate 1. The touch layer 4 is located on a side of the light-transmitting shielding layer 5 facing away from the substrate 1.

According to the display panel 100 in this embodiment of the present application, the display panel 100 includes a substrate 1, an isolation structure 2, a light-emitting functional layer 3, a light-transmitting shielding layer 5, and a touch layer 4. The isolation structure 2 is arranged on the substrate 1 and is configured to enclose a plurality of defining openings 23 to isolate the light-emitting functional layer 3 to form mutually disconnected light-emitting portions 31, thereby reducing crosstalk of carriers in the light-emitting functional layer 3 and improving a display effect of display panel 100. Moreover, the light-emitting portion 31 is disposed without a precision mask, which can reduce development and use of the precision mask and reduce manufacturing costs. The isolation structure 2 is provided with the light-transmitting opening 24, which can increase transmittance of the display panel 100. The light-transmitting shielding layer 5 includes a light-transmitting blocking portion 410, and an orthographic projection of the light-transmitting opening 24 on the substrate 1 is located within an orthographic projection of the light-transmitting blocking portion 410 on the substrate 1, that is, the light-transmitting blocking portion 410 covers the light-transmitting opening 24, so that it is difficult for touch signals and array signals to pass through the light-transmitting opening 24, so as to alleviate the problem of mutual interaction between a touch signal of the touch layer 4 and an array signal of the substrate 1 through the light-transmitting opening 24, thereby improving operational performance of OLED display products.

The substrate 1 may be arranged in a variety of manners. For example, the substrate 1 may include a base and an array substrate arranged on the base. Alternatively, the substrate 1 is a base. Alternatively, the substrate 1 includes a buffer layer and a support plate on a side facing away from the base.

In some optional embodiments, an orthographic projection of the touch layer 4 on the substrate 1 is overlapped with the orthographic projection of the isolation structure 2 on the substrate 1, but the orthographic projection of the touch layer 4 on the substrate 1 is not overlapped with the orthographic projection of the light-transmitting opening 24 on the substrate 1, which prevents an influence on a light-transmitting effect due to blocking of the light-transmitting opening 24 by the touch electrode of the touch layer 4.

In some optional embodiments, the first planarization layer 6 includes a transparent filling portion 600 arranged in the light-transmitting opening 24, and the light-transmitting shielding layer 5 is located on a side of the transparent filling portion 600 facing away from the substrate 1.

In such optional embodiments, the transparent filling portion 600 fills the light-transmitting opening 24 to alleviate the problem of disconnection of the light-transmitting blocking portion 410 due to a larger depth of the light-transmitting opening 24 during the manufacturing of the light-transmitting blocking portion 410. Optionally, the transparent filling portion 600 includes an OCA.

In some optional embodiments, a distance between a surface of the transparent filling portion 600 facing away from the substrate 1 and the substrate 1 is a first distance D1, a distance between a surface of the isolation structure 2 facing away from the substrate 1 and the substrate 1 is a second distance D2, and the first distance D1 is less than or equal to the second distance D2.

In such optional embodiments, the first distance D1 is less than or equal to the second distance D2, that is, the surface of the transparent filling portion 600 facing away from the substrate 1 is flush with the surface of the isolation structure 2 facing away from the substrate 1 or the surface of the transparent filling portion 600 facing away from the substrate 1 is lower than the surface of the isolation structure 2 facing away from the substrate 1, so that the light-transmitting opening 24 is planarized and can be continuously formed on the transparent filling portion 600, further reducing a risk of disconnection of the light-transmitting blocking portion 410 at the light-transmitting opening 24.

Optionally, the transparent filling portion 600 includes a transparent organic material.

In some embodiments, the light-transmitting shielding layer 5 includes a plurality of light-transmitting blocking portions 410, the plurality of light-transmitting blocking portions 410 are spaced apart, and the orthographic projections of the light-transmitting openings 24 on the substrate 1 are located within orthographic projections of the light-transmitting blocking portions 410 on the substrate 1.

The light-transmitting blocking portions 410 are arranged at dot-like intervals, so that the light-transmitting blocking portions 410 may be connected to different conductive structures respectively. The light-transmitting blocking portions 410 may have different potentials to provide different blocking capabilities.

Referring to FIG. 12, FIG. 12 is a partial sectional view of a display panel in another embodiment.

As shown in FIG. 12, in some optional embodiments, the display panel 100 further includes a first electrode layer 320, the first electrode layer 320 is located on a side of the light-emitting functional layer 3 facing away from the substrate 1, the first electrode layer 320 includes first electrodes 32 in the defining openings 23, the first electrodes 32 are electrically connected to the isolation structure 2, and the light-transmitting blocking portions 410 are electrically connected to the isolation structure 2.

In such optional embodiments, the isolation structure 2 isolates the first electrode layer 320 to form mutually spaced first electrodes 32. The mutually spaced first electrodes 32 are electrically connected through the isolation structure 2 to form an entire-surface electrode, ensuring normal light emission of the light-emitting portion 31. The light-transmitting blocking portions 410 connects the isolation structure 2 around the light-transmitting opening 24 to increase an electrical conduction area of the entire-surface electrode and reduce overall impedance, thereby reducing power consumption of the display panel 100. The light-transmitting blocking portions 410 are electrically connected to the isolation structure 2, that is, the light-transmitting blocking portions 410 are electrically connected to the first electrodes 32, so that the light-transmitting blocking portions 410 and the first electrodes 32 have same potentials, thereby realizing a blocking function of the light-transmitting shielding layer 5.

In some optional embodiments, an orthographic projection of each light-emitting portion 31 on the substrate 1 is located within an orthographic projection of each first electrode 32 on the substrate 1.

In such optional embodiments, the orthographic projections of the light-emitting portions 31 on the substrate 1 are located within the orthographic projections of the first electrodes 32 on the substrate 1, that is, the first electrodes 32 cover the light-emitting portions 31 to serve as electrodes of the light-emitting portions 31 to ensure normal light emission of the light-emitting portion 31, improving the display effect of the display panel 100.

Optionally, the light-emitting portions 31 are spaced apart from the isolation structure 2, and the light-emitting functional layer 3 is spaced apart from the isolation structure 2. That is, the light-emitting portions 31 are spaced apart from each other to reduce crosstalk of carriers between the light-emitting portions 31 and alleviate the problem of cross color of the light-emitting portions 31.

In some optional embodiments, the isolation structure 2 includes a first conductive layer 210 and a second conductive layer 220, the second conductive layer 220 is located on a side of the first conductive layer 210 facing away from the substrate 1, the light-transmitting blocking portions 410 are electrically connected to the second conductive layer 220, and the first electrodes 32 are electrically connected to the first conductive layer 210.

In such optional embodiments, the first conductive layer 210 and the second conductive layer 220 are arranged to form the isolation structure 2, and the light-transmitting blocking portion 410 is overlapped with the second conductive layer 220 to achieve electrical conduction between the light-transmitting blocking portion 410 and the first electrode 32. The first electrode 32 is overlapped with the first conductive layer 210, so that the first electrodes 32 are connected to each other through the first conductive layer 210.

In some optional embodiments, an edge of the light-transmitting blocking portion 410 extends to a side of the second conductive layer 220 facing away from the substrate 1 and is in contact with the side of the second conductive layer 220 facing away from the substrate 1. The electrical conduction between the light-transmitting blocking portions 410 and the first electrodes 32 can be further achieved.

In some optional embodiments, an orthographic projection of the first conductive layer 210 on the substrate 1 is located within an orthographic projection of the second conductive layer 220 on the substrate 1.

In such optional embodiments, the orthographic projection of the first conductive layer 210 arranged close to the substrate 1 on the substrate 1 is located within the orthographic projection of the second conductive layer 220 on the substrate 1, an area of the second conductive layer 220 is greater than that of the first conductive layer 210, and the second conductive layer 220 covers a surface of the first conductive layer 210 close to the second conductive layer 220. In this case, the first conductive layer 210 is recessed relative to the second conductive layer 220 in a direction away from the defining opening 23. When the light-emitting functional layer 3 is disposed, the light-emitting functional layer 3 has a large drop at an edge of the isolation structure 2, and the first conductive layer 210 is concavely arranged relative to the second conductive layer 220. It is difficult to connect the light-emitting functional layer 3 at the edge of the isolation structure 2, thereby resulting in breakage. The light-emitting functional layer 3 breaks to form light-emitting portions 31 disconnected from each other.

In some optional embodiments, the second conductive layer 220 includes a metal material, and materials of the first conductive layer 210 and the second conductive layer 220 are different.

In such optional embodiments, when the first conductive layer 210 and the second conductive layer 220 are both made of metal materials, the first conductive layer 210 may be wet etched by using an etching solution. Through the arrangement of the etching solution, an etching rate of the second conductive layer 220 can be made lower than that of the first conductive layer 210. Since the etching rate of the first conductive layer 210 is relatively high, when the etching solution is used for wet etching, even though the second conductive layer 220 may be etched to some extent, the first conductive layer 210 will be etched faster. As a result, the first conductive layer 210 is concavely arranged relative to the second conductive layer 220.

In some optional embodiments, the isolation structure 2 further includes a third layer 230 located on a side of the first conductive layer 210 facing the substrate 1, and an orthographic projection of the first conductive layer 210 on the substrate 1 is located within an orthographic projection of the third layer 230 on the substrate 1.

In such optional embodiments, in order to obtain the first conductive layer 210 concavely arranged, during the etching, the first conductive layer 210 has a faster etching rate than the second conductive layer 220 and the third layer 230, thereby forming the concave first conductive layer 210. Since the etching rate of the first conductive layer 210 is faster, more waste generated by the etching can easily enter other positions of the display panel 100, thereby causing adverse effects. After the third layer 230 is arranged, the first conductive layer 210 can be better attached to the third layer 230, and etching waste generated falls on the third layer 230, which is easy to clean.

Optionally, the light-transmitting blocking portion 410 includes indium tin oxide (ITO) or indium zinc oxide (IZO). When made of ITO or IZO, the light-transmitting blocking portion 410 has better transmittance and can be electrically conductive to the isolation structure 2.

In some optional embodiments, an orthographic projection of the isolation structure 2 on the substrate 1 is at least partially overlapped with an orthographic projection of the light-transmitting blocking portion 410 on the substrate 1.

In such optional embodiments, the isolation structure 2 is at least partially overlapped with the light-transmitting blocking portion 410, so that the isolation structure 2 and the light-transmitting blocking portion 410 may have a good contact, and an overlapping area between the isolation structure 2 and the light-transmitting blocking portion 410 is large, which can reduce overlapping impedance of the isolation structure 2 and the light-transmitting blocking portion 410 and improve a blocking effect of the light-transmitting blocking portion 410.

In some optional embodiments, an orthographic projection of the second conductive layer 220 on the substrate 1 is at least partially overlapped with an orthographic projection of the light-transmitting blocking portion 410 on the substrate 1.

In such optional embodiments, the second conductive layer 220 is at least partially overlapped with the light-transmitting blocking portion 410, so that the second conductive layer 220 and the light-transmitting blocking portion 410 may have a good contact, and an overlapping area between the second conductive layer 220 and the light-transmitting blocking portion 410 is large, which can reduce overlapping impedance of the second conductive layer 220 and the light-transmitting blocking portion 410 and improve a blocking effect of the light-transmitting blocking portion 410.

Optionally, an orthographic projection of the second conductive layer 220 of the isolation structure 2 located around the light-transmitting opening 24 on the substrate 1 is overlapped with the orthographic projection of the light-transmitting blocking portion 410 on the substrate 1, which can further increase the overlapping area between the light-transmitting blocking portion 410 and the second conductive layer 220 and improve an overlapping effect between the light-transmitting blocking portion 410 and the second conductive layer 220 and can also reduce the overlapping impedance of the second conductive layer 220 and the light-transmitting blocking portion 410 and improve the blocking effect of the light-transmitting blocking portion 410.

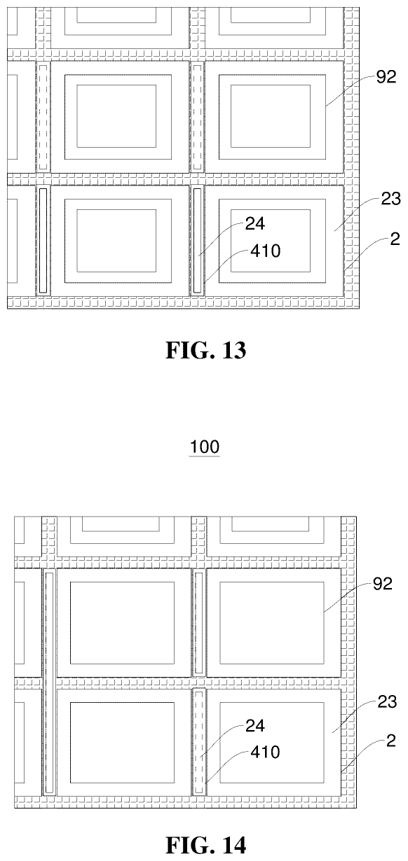

Referring to FIG. 13 and FIG. 14 together, FIG. 13 is a schematic top view of a display panel according to an embodiment of the present application; and FIG. 14 is a partial top view of a display panel in another embodiment.

In some optional embodiments, as shown in FIG. 13, one light-transmitting blocking portion 410 is arranged corresponding to one light-transmitting opening 24, and/or as shown in FIG. 14, one light-transmitting blocking portion 410 is arranged corresponding to a plurality of light-transmitting openings 24.

“One light-transmitting blocking portion 410 is arranged corresponding to one light-transmitting opening 24” means that an orthographic projection of one light-transmitting opening 24 on the substrate 1 is located within an orthographic projection of one light-transmitting blocking portion 410. “One light-transmitting blocking portion 410 is arranged corresponding to a plurality of light-transmitting openings 24” means that orthographic projections of a plurality of light-transmitting openings 24 on the substrate 1 are located within an orthographic projection of a same light-transmitting blocking portion 410.

In such optional embodiments, one light-transmitting blocking portion 410 is arranged corresponding to one light-transmitting opening 24, which can reduce an overall area of the light-transmitting blocking portion 410 and reduce material costs. One light-transmitting blocking portion 410 is arranged corresponding to a plurality of light-transmitting openings 24, which can increase an overlapping area between the light-transmitting blocking portion 410 and the isolation structure 2, reduce overlapping impedance, and improve the blocking effect of the light-transmitting blocking portion 410.

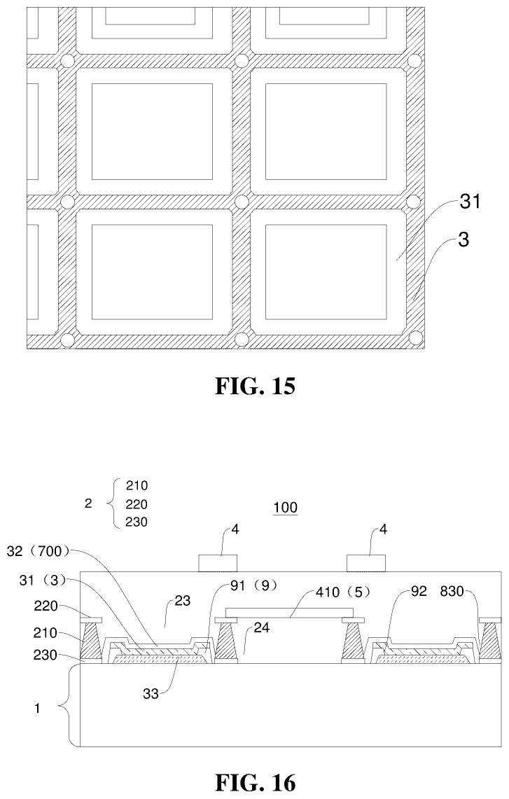

Referring to FIG. 15, FIG. 15 is a partial top view of a display panel in yet another embodiment.

Optionally, as shown in FIG. 13 and FIG. 14, the light-transmitting openings 24 are arranged between two adjacent defining openings 23, or as shown in FIG. 15, an orthographic projection of the isolation structure 2 on the substrate 1 is grid-like and has grid intersection positions, and the light-transmitting openings 24 are arranged at the grid intersection positions. At the grid intersection positions, the orthographic projection of the isolation structure 2 on the substrate 1 has a larger area, which facilitates manufacturing of the light-transmitting opening 24, and larger light-transmitting openings 24 can be disposed at the grid intersection positions to increase a high-transmittance area of the display panel 100.

Referring to FIG. 16, FIG. 16 is a partial sectional view of a display panel in yet another embodiment.

In some optional embodiments, the display panel 100 further includes a pixel defining layer 9, the pixel defining layer 9 is located on the substrate 1, the pixel defining layer 9 includes a pixel defining portion 91 and a pixel opening 92 formed by enclosing the pixel defining portion 91, an orthographic projection of the pixel opening 92 on the substrate 1 is located within the orthographic projection of the defining opening 23 on the substrate 1, and the light-emitting portion 31 is located in the pixel opening 92.

In such optional embodiments, the pixel opening 92 formed by enclosing the pixel defining portion 91 is configured to arrange the light-emitting portion 31 to realize light-emitting display of the display panel 100. “An orthographic projection of the pixel opening 92 on the substrate 1 is located within the orthographic projection of the defining opening 23 on the substrate 1” means that the pixel opening 92 is completely exposed from the defining opening 23, which reduces blocking of the pixel opening 92 by the isolation structure 2 and ensures a light-emitting effect of the light-emitting portion 31.

In some optional embodiments, the isolation structure 2 is located on a side of the pixel defining portion 91 facing away from the substrate 1.

In such optional embodiments, the isolation structure 2 is arranged on the pixel defining portion 91, and the isolation structure 2 is equivalent to the pixel opening 92 having a large height drop. When the light-emitting functional layer 3 is disposed, due to the large drop, the light-emitting functional layer 3 is easier to be disconnected at the isolation structure 2, which reduces difficulty of manufacturing the light-emitting functional layer 3.

As shown in FIG. 16, in some optional embodiments, the pixel defining portion 91 is provided with an accommodating opening 830, and the isolation structure 2 is located in the accommodating opening 830.

In such optional embodiments, the isolation structure 2 is arranged in the accommodating opening 830 in the pixel defining portion 91. During the manufacturing, the isolation structure 2 is disposed prior to manufacturing of the second electrode 33, that is, after the isolation structure 2 is disposed on the substrate 1, the second electrode 33 is disposed on the substrate 1, to reduce an influence of the manufacturing of the isolation structure 2 on the second electrode 33, ensuring no damage to the second electrode 33.

In some optional embodiments, the display panel 100 further includes a second electrode 33, and the second electrode 33 is exposed from the pixel opening 92.

Optionally, the display panel 100 further includes a second electrode 33 exposed from the pixel opening 92, one of the second electrode 33 and the first electrode 32 serves as an anode of the light-emitting portion 31, and the other serves as a cathode of the light-emitting portion 31. The embodiments of the present application are illustrated based on an example in which the second electrode 33 serves as the anode of the light-emitting portion 31 and the first electrode 32 serves as the cathode of the light-emitting portion 31.

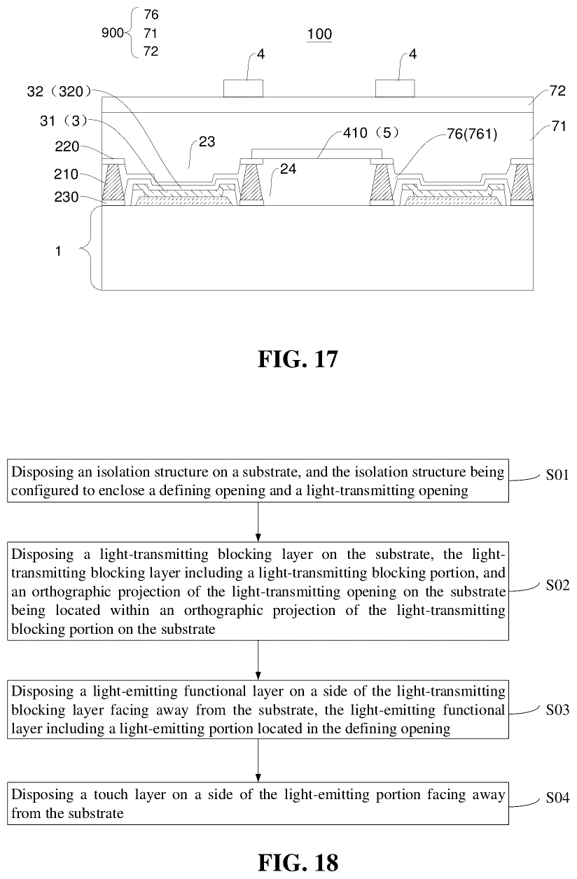

Referring to FIG. 17, FIG. 17 is a partial sectional view of a display panel in still another embodiment.

As shown in FIG. 17, in some optional embodiments, the display panel 100 further includes a third encapsulation layer 76, the third encapsulation layer 76 is located on a side of the first electrode layer 320 facing away from the substrate 1, and the touch layer 4 is located on a side of the third encapsulation layer 76 facing away from the substrate 1.

In such optional embodiments, the third encapsulation layer 76 is arranged on the side of the first electrode layer 320 facing away from the substrate 1, so as to encapsulate the first electrode layer 320 and the light-emitting functional layer 3, which reduces a possibility of water and oxygen intrusion and prolongs the service life of the display panel 100.

In some optional embodiments, the third encapsulation layer 76 includes an encapsulation portion 761, and the encapsulation portion 761 is located in the defining opening 23 and located on a side of the light-emitting portion 31 facing away from the substrate 1.

In such optional embodiments, the encapsulation portion 761 is arranged on the side of the first electrode layer 320 facing away from the substrate 1, so as to encapsulate the first electrode layer 320 and the light-emitting functional layer 3, which reduces a possibility of water and oxygen intrusion and prolongs the service life of the display panel 100.

Optionally, the third encapsulation layer 76 includes an inorganic material, and the inorganic material is denser and has better barrier properties against water vapor and oxygen.

In some optional embodiments, the display panel 100 further includes a first encapsulation layer 71, the first encapsulation layer 71 is located on the side of the third encapsulation layer 76 facing away from the substrate 1, and the first encapsulation layer 71 covers the light-transmitting shielding layer 5.

In such optional embodiments, the display panel 100 includes the third encapsulation layer 76 and the first encapsulation layer 71, and the third encapsulation layer 76 and the first encapsulation layer 71 are used for multi-layer encapsulation to further improve encapsulation performance of an encapsulation layer 900.

Optionally, the first encapsulation layer 71 includes an organic material, and the first encapsulation layer 71 is encapsulated by using the organic material, which further improves the encapsulation performance of the display panel 100.

Optionally, the display panel 100 further includes a second encapsulation layer 72, and the second encapsulation layer 72 is located on the side of the first encapsulation layer 71 facing away from the substrate 1. The display panel 100 adopts three-layer encapsulation, which has better encapsulation performance and reduces the possibility of water and oxygen intrusion.

Optionally, the second encapsulation layer 72 includes an inorganic material, and the third encapsulation layer 76, the first encapsulation layer 71, and the second encapsulation layer 72 are respectively encapsulated by using an inorganic material, an organic material, and an inorganic material to form a thin film encapsulation (TFE) structure, which further improves the encapsulation performance of the display panel 100. The third encapsulation layer 76, the first encapsulation layer 71, and the second encapsulation layer 72 may be sequentially arranged to form the encapsulation layer 900.

Optionally, the light-emitting portion 31 includes an electron injection layer (EIL), an electron transport layer (ETL), a light-emitting material layer, a hole injection layer (HIL), and a hole transport layer (HTL).

The structural design in this embodiment may be applied to other display panels 100, and a specific selection may be made according to an actual situation, which is not specifically limited in the present application.

An embodiment of a second aspect of the present application further provides a display apparatus, including the display panel 100 in any one of the embodiments in the first aspect. Since the display apparatus provided in the embodiment of the second aspect of the present application includes the display panel 100 in any one of the above embodiments in the first aspect, the display apparatus provided in the embodiment of the second aspect of the present application has the beneficial effects of the display panel 100 in any one of the above embodiments in the first aspect. Details are not described herein again.

The display apparatus in the embodiments of the present application includes, but is not limited to, a mobile phone, a personal digital assistant (PDA), a tablet computer, an e-book, a television, an access control, a smart fixed phone, a console, and other devices with a display function.

An embodiment of a third aspect of the present application further provides a manufacturing method for a display panel 100. The display panel 100 may be the display panel 100 in any one of the above embodiments in the first aspect. Referring to FIG. 1 and FIG. 17 together and FIG. 18, FIG. 18 is a schematic flowchart of a display panel manufacturing method according to an embodiment of the present application. The manufacturing method includes the following steps.

In S01, an isolation structure is disposed on a substrate, the isolation structure being configured to enclose a defining opening and a light-transmitting opening.

In S02, a light-transmitting shielding layer is disposed on the substrate, the light-transmitting shielding layer including a light-transmitting blocking portion, and an orthographic projection of the light-transmitting opening on the substrate being located within an orthographic projection of the light-transmitting blocking portion on the substrate.

In S03, a light-emitting functional layer is disposed on a side of the light-transmitting shielding layer facing away from the substrate, the light-emitting functional layer including a light-emitting portion located in the defining opening.

In S104, a touch layer is disposed on a side of the light-emitting portion facing away from the substrate.

In the method according to the embodiment of the third aspect of the present application, at S01, an isolation structure 2 is disposed on a substrate 1, and the isolation structure 2 is configured to enclose a defining opening 23 and a light-transmitting opening 24. Then, at S02, a light-transmitting shielding layer 5 is disposed on the substrate 1. At S03, a light-emitting functional layer 3 is disposed on a side of the light-transmitting shielding layer 5 facing away from the substrate 1. Finally, at 504, a touch layer 4 is disposed on a side of the light-emitting functional layer 3 facing away from the substrate 1. The isolation structure 2 is arranged on the substrate 1 and is configured to enclose a plurality of defining openings 23 to partition the light-emitting functional layer 3 to form mutually disconnected light-emitting portions 31, thereby reducing crosstalk of carriers in the light-emitting functional layer 3 and improving a display effect of display panel 100. Moreover, the light-emitting portion 31 is disposed without a precision mask, which can reduce development and use of the precision mask and reduce manufacturing costs. The isolation structure 2 is provided with the light-transmitting opening 24, which can increase transmittance of the display panel 100. The light-transmitting shielding layer 5 includes a light-transmitting blocking portion 410, and an orthographic projection of the light-transmitting opening 24 on the substrate 1 is located within an orthographic projection of the light-transmitting blocking portion 410 on the substrate 1, that is, the light-transmitting blocking portion 410 covers the light-transmitting opening 24, so that it is difficult for touch signals and array signals to pass through the light-transmitting opening 24, so as to alleviate the problem of mutual interaction between a touch signal of the touch layer 4 and an array signal of the substrate 1 through the light-transmitting opening 24, thereby improving operational performance of OLED display products.

In some optional embodiments, prior to S03, the method further includes: disposing a pixel defining material layer on the substrate 1.

Subsequent to S02, the method further includes: patterning the pixel defining material layer to obtain a pixel defining layer 9, the pixel defining layer 9 including a pixel defining portion 91 and a pixel opening 92 formed by enclosing the pixel defining portion 91, an orthographic projection of the pixel opening 92 on the substrate 1 being located within an orthographic projection of the defining opening 23 on the substrate 1, and the light-emitting portion 31 being located in the pixel opening 92.

In such optional embodiments, the pixel defining material layer is disposed after the manufacturing of the light-transmitting shielding layer 5, the light-transmitting shielding layer 5 covers the light-transmitting opening 24, and by using a normal mask, the pixel defining material layer may be etched to form the pixel opening 92, thereby simplifying the manufacturing process of the display panel 100.

In accordance with the embodiments of the present application as described above, these embodiments are not intended to be exhaustive or to limit the present application to the specific embodiments disclosed. Obviously, many modifications and variations are possible according to the above description. The embodiments are chosen and described in the specification in order to best explain the principles and the practical application of the present application, so as to enable those skilled in the art to well utilize the present application and modifications based on the present application. The present application is to be limited only by the claims and full scope and equivalents thereof.

What is claimed is:

1. A display panel, comprising:
a substrate;
an isolation structure arranged on a side of the substrate, the isolation structure being configured to enclose a plurality of defining openings and a plurality of light-transmitting openings;
a light-emitting functional layer comprising a plurality of light-emitting portions, each of the plurality of light-emitting portions being at least partially arranged in the defining opening;
a touch layer arranged on a side of the isolation structure facing away from the substrate; and
a light-transmitting shielding layer arranged between the isolation structure and the touch layer, an orthographic projection of the light-transmitting shielding layer on the substrate being at least partially overlapped with an orthographic projection of the light-transmitting opening on the substrate.

2. The display panel of claim 1, wherein the display panel further comprises a first planarization layer, the light-transmitting shielding layer is arranged on a side of the first planarization layer facing away from the substrate, and at least part of the first planarization layer is arranged in the light-transmitting opening.

3. The display panel of claim 2, wherein the first planarization layer covers a side of the isolation structure facing away from the substrate, the first planarization layer covers a side of the light-emitting functional layer facing away from the substrate, and the display panel further comprises a first encapsulation layer, the first encapsulation layer is arranged between the first planarization layer and the touch layer, and the first encapsulation layer covers a side of the light-transmitting shielding layer facing away from the substrate.

4. The display panel of claim 1, wherein at least part of the touch layer is electrically connected to the light-transmitting shielding layer.

5. The display panel of claim 4, wherein the display panel further comprises a first encapsulation layer, the first encapsulation layer covers a side of the light-transmitting shielding layer facing away from the substrate, the first encapsulation layer comprises a first opening, the light-transmitting shielding layer is exposed by the first opening, and at least part of the touch layer is electrically connected to the light-transmitting shielding layer by the first opening.

6. The display panel of claim 5, wherein the display panel comprises a display region and a non-display region connected to each other, and the first opening is located in the non-display region.

7. The display panel of claim 5, wherein the display panel further comprises a first planarization layer, the first encapsulation layer is arranged between the first planarization layer and the touch layer, the light-transmitting shielding layer is arranged on a side of the first planarization layer facing away from the substrate, the light-transmitting shielding layer further comprises a plurality of first vias, the first planarization layer and the first encapsulation layer are in contact through the plurality of first vias, and an orthographic projection of the light-emitting portion on the light-transmitting shielding layer is at least partially overlapped with the first via.

8. The display panel of claim 1, wherein the display panel further comprises:
a first electrode layer located on a side of the light-emitting portion facing away from the substrate, the first electrode layer comprises a first electrode located in the defining opening, and the first electrode is electrically connected to the light-transmitting shielding layer.

9. The display panel of claim 1, wherein the display panel further comprises a first planarization layer and a first electrode layer, the light-transmitting shielding layer is arranged on a side of the first planarization layer facing away from the substrate, the first electrode layer is located on a side of the light-emitting portion facing away from the substrate, the first electrode layer comprises a first electrode located in the defining opening, the isolation structure comprises a conductive layer, edges of the first electrode are in contact with the conductive layer, the first planarization layer comprises a second opening, the conductive layer is exposed by the second opening, a portion of the light-transmitting shielding layer is arranged in the second opening and is electrically connected to the conductive layer, and the display panel comprises a display region and a non-display region connected to each other, the conductive layer comprises a main body portion located in the display region and a frame portion located in the non-display region, the second opening is located in the non-display region, the light-transmitting shielding layer is spaced apart from the main body portion, and the light-transmitting shielding layer is connected to the frame portion exposed to the second opening.

10. The display panel of claim 1, wherein the light-transmitting opening is located between the adjacent defining openings; or
an orthographic projection of the isolation structure on the substrate is grid-like and has a grid intersection position, and the light-transmitting opening is arranged at the grid intersection position.

11. The display panel of claim 1, wherein along a direction from the touch layer to the substrate, the orthographic projection of the light-transmitting shielding layer on the substrate is at least partially overlapped with an orthographic projection of the isolation structure on the substrate.

12. The display panel of claim 1, wherein the isolation structure comprises a first isolation portion and a second isolation portion stacked on the first isolation portion, the first isolation portion is arranged on a side of the second isolation portion close to the substrate, and an orthographic projection of the first isolation portion on the substrate is located within an orthographic projection of the second isolation portion on the substrate.

13. The display panel of claim 1, wherein the display panel further comprises a pixel defining layer arranged between the substrate and the isolation structure, the pixel defining layer comprises a plurality of pixel openings, an orthographic projection of the pixel opening on the substrate is located within a range of an orthographic projection of the defining opening on the substrate, and the isolation structure is arranged on a side of the pixel defining layer facing away from the substrate, and at least part of the light-emitting portion is arranged in the pixel opening.

14. The display panel of claim 2, wherein the first planarization layer comprises a transparent filling portion arranged in the light-transmitting opening, and the light-transmitting shielding layer is located on a side of the transparent filling portion facing away from the substrate.

15. The display panel of claim 14, wherein a distance between a surface of the transparent filling portion facing away from the substrate and the substrate is a first distance, and a distance between a surface of the isolation structure facing away from the substrate and the substrate is a second distance, and the first distance is less than or equal to the second distance.

16. The display panel of claim 14, wherein the light-transmitting shielding layer comprises a plurality of light-transmitting blocking portions, the plurality of light-transmitting blocking portions are spaced apart, and the orthographic projection of the light-transmitting opening on the substrate is located within an orthographic projection of the light-transmitting blocking portion on the substrate.

17. The display panel of claim 16, wherein the display panel further comprises:
a first electrode layer located on a side of the light-emitting portion facing away from the substrate, the first electrode layer comprises a first electrode located in the defining opening, the first electrode is electrically connected to the isolation structure, and the light-transmitting blocking portion is electrically connected to the isolation structure.

18. The display panel of claim 17, wherein the isolation structure further comprises a first conductive layer and a second conductive layer, the second conductive layer is located on a side of the first conductive layer facing away from the substrate, the light-transmitting blocking portion is electrically connected to the second conductive layer, and the first electrode is electrically connected to the first conductive layer.

19. The display panel of claim 17, wherein the display panel further comprises a third encapsulation layer, the third encapsulation layer is located on a side of the first electrode layer facing away from the substrate, and the touch layer is located on a side of the third encapsulation layer facing away from the substrate; and
the third encapsulation layer comprises a plurality of encapsulation portions, the encapsulation portion is located within the defining opening and on a side of the light-emitting portion facing away from the substrate, and the display panel further comprises a first encapsulation layer, the first encapsulation layer is located on a side of the third encapsulation layer facing away from the substrate, and the first encapsulation layer covers the light-transmitting shielding layer.

20. A display apparatus, comprising the display panel of claim 1.
